(19) United States
(12) Patent Application Publication
(10) Pub. No.: US 2013/0181307 A1
(43) Pub. Date: Jul. 18, 2013

(54) METHOD OF MANUFACTURING SEMICONDUCTOR DEVICE AND SEMICONDUCTOR DEVICE

(71) Applicant: Atsushi OHTA, Oita (JP)

(72) Inventor: Atsushi OHTA, Oita (JP)

(73) Assignee: Kabushiki Kaisha Toshiba, Tokyo (JP)

(21) Appl. No.: 13/472,796

(22) Filed: May 16, 2012

(30) Foreign Application Priority Data
Jan. 17, 2012 (JP) 2012-007443

(51) Int. Cl. H01L 27/14; H01L 31/18

(52) U.S. Cl. 257/431; 438/98; 257/E27.122; 257/E31.001

(57) ABSTRACT

According to an embodiment, a method of manufacturing a semiconductor device is provided. The method of manufacturing a semiconductor device includes forming a blocking film by a material including at least carbon on an upper surface of a second element among a first element and the second element formed on a semiconductor substrate, the blocking film configured to inhibit the second element from turning into salicide.

### CROSS-REFERENCE TO RELATED APPLICATIONS

This application is based upon and claims the benefit of priority from Japanese Patent Application No. 2012-007443, filed on Jan. 17, 2012; the entire contents of which are incorporated herein by reference.

### FIELD

Embodiments described herein relate generally to a method of manufacturing a semiconductor device and the semiconductor device.

### BACKGROUND

Conventionally, there is a semiconductor device that includes a first element whose upper surface has been turned into salicide, a second element whose upper surface has not been turned into salicide, and contact electrodes that reach upper surfaces of the first element and the second element from an upper surface of an insulating film formed on the first element and the second element.

In manufacturing such a semiconductor device, for example, a blocking film that inhibits formation of salicide is formed on the upper surface of the second element by the insulating film after having formed the first element and the second element, and then the upper surface of the first element is selectively turned into salicide by performing a salicide process.

Next, after having formed the insulating film on the first element and the second element onto whose upper surface the blocking film has been formed, a first contact hole is formed from the upper surface of the insulating film toward the upper surface of the first element, and a second contact hole is formed from the upper surface of the insulating film toward the upper surface of the second element. Then, the contact electrodes are formed by embedding metal in the first contact hole and the second contact hole.

Here, the first contact hole is formed by etching the insulating film formed on the first element. On the other hand, the second contact hole is formed by etching the blocking film and the insulating film formed on the second element.

Due to this, in simultaneously forming the first contact hole and the second contact hole by an etching condition for forming the second contact hole, the first contact hole may reach a layer lower than a target layer, and there is a risk that a yield might be reduced.

### BRIEF DESCRIPTION OF THE DRAWINGS

FIG. 1A to FIG. 4C are schematic cross sectional views showing a manufacturing process of a semiconductor device of a first embodiment;

FIG. 5A to FIG. 6C are schematic cross sectional views showing a manufacturing process of a semiconductor device of a second embodiment;

FIG. 7 is a schematic cross sectional view showing the semiconductor device formed by using the manufacturing method of the second embodiment, having a resistive element at an upper surface portion of a gate electrode.

### DETAILED DESCRIPTION

According to an embodiment, a method of manufacturing a semiconductor device is provided. The method of manufacturing a semiconductor device includes forming a blocking film by a material including at least carbon on an upper surface of a second element among a first element and the second element formed on a semiconductor substrate, the blocking film configured to inhibit the second element from turning into salicide.

Hereinbelow, embodiments of a method of manufacturing a semiconductor device and the semiconductor device will be explained in detail with reference to the attached drawings. Note that, the present invention is not limited by the embodiments shown below.

### First Embodiment

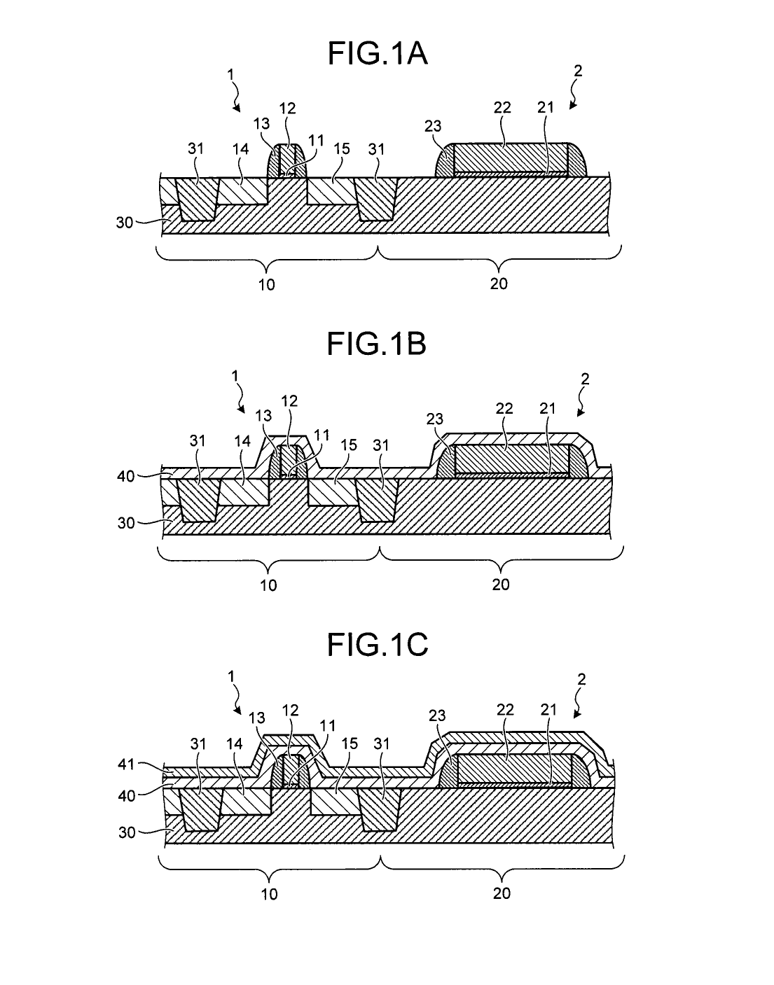

FIG. 1A to FIG. 4C are schematic cross sectional views showing a manufacturing process of a semiconductor device of a first embodiment. Hereinbelow, a process of forming a MOSFET (Metal Oxide Semiconductor Field Effect Transistor (hereafter simply described as “FET”)) in a logic region and a pixel region of a backside illuminating type solid-state imaging device will be explained. Note that, the manufacturing method of the first embodiment can be adapted to a method of manufacturing a semiconductor device as desired, such as a resistive element, a capacitor, a diode, and a transistor.

Generally, the FET formed in the logic region of the solid-state imaging device is required of a faster operation than the FET formed in the pixel region. Due to this, different from the FET formed in the pixel region, in the FET formed in the logic region, a salicide layer is formed between a gate, a source, a drain and respective extracting electrodes.

Due to this, the FET formed in the logic region is enabled with the faster operation than the FET formed in the pixel region because of a contact resistance being reduced between the gate, the source, the drain and the respective extracting electrodes.

Accordingly, in selectively providing the salicide layer in the FET of the logic region, as shown in FIG. 1A for example, firstly, a FET (hereafter described as “first element 1”) is formed in a logic region 10 on a semiconductor substrate. On the other hand, a FET (hereafter described as “second element 2”) is formed in a pixel region 20 on the semiconductor substrate.

Specifically, after having formed a silicon oxide film on a semiconductor layer 30 formed on the semiconductor substrate and in which N-type impurity ions are doped, the silicon oxide film is exfoliated at regions other than regions that are to be a gate of the first element 1 and a gate of the second element 2. Due to this, a gate oxide film 11 of the first element 1 and a gate oxide film 21 of the second element 2 are formed.

Next, electrodes made by a material for example of polysilicon are formed on the gate oxide film 11 of the first element 1 and the gate oxide film 21 of the second element 2. Due to this, a gate electrode 12 of the first element 1 and a gate electrode 22 of the second element 2 are formed.

Then, insulating films made by a material for example of silicon nitride are formed at a side surface of the gate electrode 12 and the gate oxide film 11 of the first element 1 and a side surface of the gate electrode 22 and the gate oxide film 21 of the second element 2. Due to this, a sidewall 13 of the first element 1 and a sidewall 23 of the second element 2 are formed.

Next, a source region 14 and a drain region 15 of the first element 1 are formed in the logic region 10 in the semiconductor layer 30, and a source region and a drain region of the second element 2 are formed in the pixel region 20.

Note that, an explanation herein will be given assuming that the source region of the second element 2 is formed at a front side in a front-rear direction of FIG. 1A, and the drain region of the second element 2 is formed at a rear side in the front-rear direction of FIG. 1A. Due to this, in FIG. 1A, the source region and the drain region of the second element 2 are not depicted.

Here, the source region 14 and the drain region 15 of the first element 1 are formed by performing an annealing process after having injected P-type impurity ions at predetermined positions in the logic region 10 of the semiconductor layer 30.

Further, the source region and the drain region of the second element 2 are formed by performing the annealing process after having injected the P-type impurity ions at predetermined positions in the pixel region 20 of the semiconductor layer 30. Note that, by embedding insulators such as silicon oxide between the logic region 10 and the pixel region 20 as well as between respective elements, an STI (Shallow Trench Isolation) 31 for element separation is formed.

Next, as shown in FIG. 1B, a blocking film 40 is formed by a material at least including carbon on the semiconductor substrate onto which the first element 1 and the second element 2 have been formed. Here, the blocking film 40 is formed by a plasma CVD (Chemical Vapor Deposition) using amorphous carbon as the material. Such a blocking film 40 is a film that inhibits the upper surface of the first element 1 from turning into salicide.

Next, as shown in FIG. 1C, a DARC (Dielectric Anti Reflection Coating) film 41 is formed on an upper surface of the blocking film 40 using the plasma CVD. Note that, a silicon oxide film may substitute the aforementioned DARC film 41.

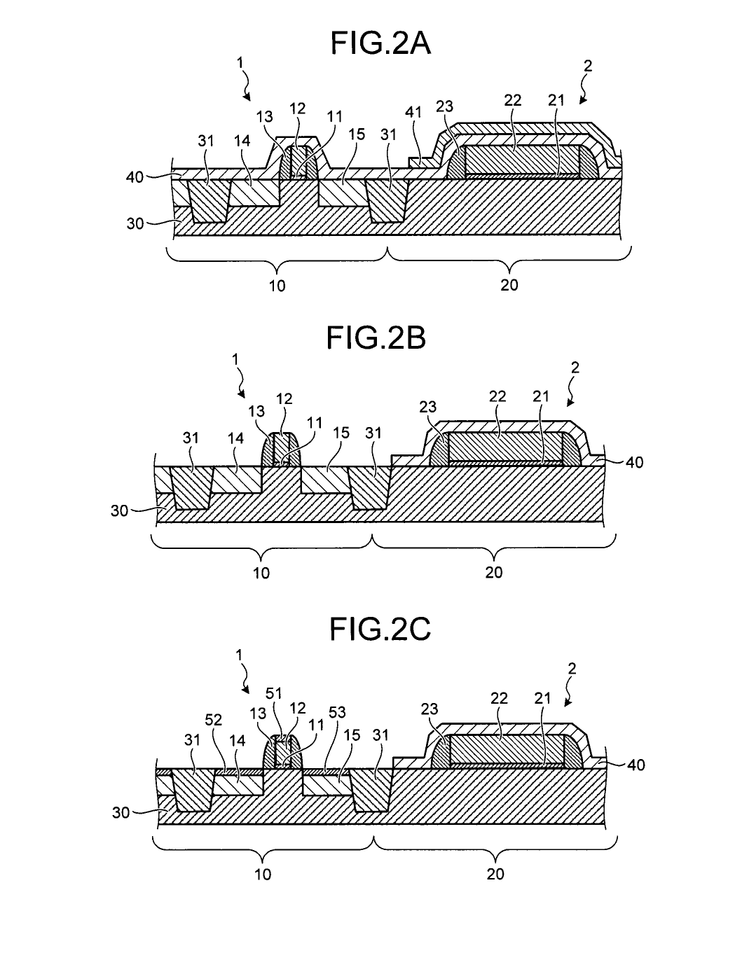

Next, as shown in FIG. 2A, the DARC film 41 formed on the first element 1 is selectively removed. For example, a resist (not shown) having an opening above the first element 1 may be formed by a photolithography, and the DARC film 41 may be selectively removed from above the first element 1 by performing an RIE (Reactive Ion Etching) using the aforementioned resist as a mask. According to this, a state in which the DARC film 41 is present on the second element 2 and the DARC film 41 is not present on the first element 1 is obtained.

Next, as shown in FIG. 2B, the blocking film 40 formed on the first element 1 is selectively removed. Here, the blocking film 40 at the portion not covered by the DARC film 41 shown in FIG. 2A is selectively removed by ashing.

In the removal of the aforementioned blocking film 40, for example, light such as ultraviolet ray is irradiated onto the blocking film 40 with the DARC film 41 shown in FIG. 2A as the mask in a process chamber into which a predetermined reaction gas is introduced. Due to this, the blocking film 40 at the portion not covered by the DARC film 41 is removed by the ashing, and a state in which the blocking film 40 is present on the second element 2 and the blocking film 40 is not present on the first element 1 is obtained. Note that, as for the DARC film 41 above the second element 2, it is removed after the aforementioned ashing.

Accordingly, in the manufacturing method of the first embodiment, since the blocking film 40 is formed by the material including carbon, unnecessary portions of the blocking film 40 can be removed by the ashing instead of the RIE.

Thus, according to the manufacturing method of the first embodiment, compared to a case of removing the unnecessary portions of the blocking film 40 by the RIE, the unnecessary portions of the blocking film 40 can be removed with no damage to the upper surface of the first element 1.

Next, heating to a predetermined temperature under the state in which the blocking film 40 is not present on the first element 1 and the blocking film 40 is present on the second element 2 is performed, and silicon on surfaces of the gate electrode 12, the source region 14 and the drain region 15 of the first element 1 and predetermined metal are reacted. Here, for example, Ti (titan) is used as the predetermined metal.

Due to this, as shown in FIG. 2C, salicide layers 51, 52, and 53 are formed at upper surface portions of the gate electrode 12, the source region 14 and the drain region 15 of the first element 1, respectively.

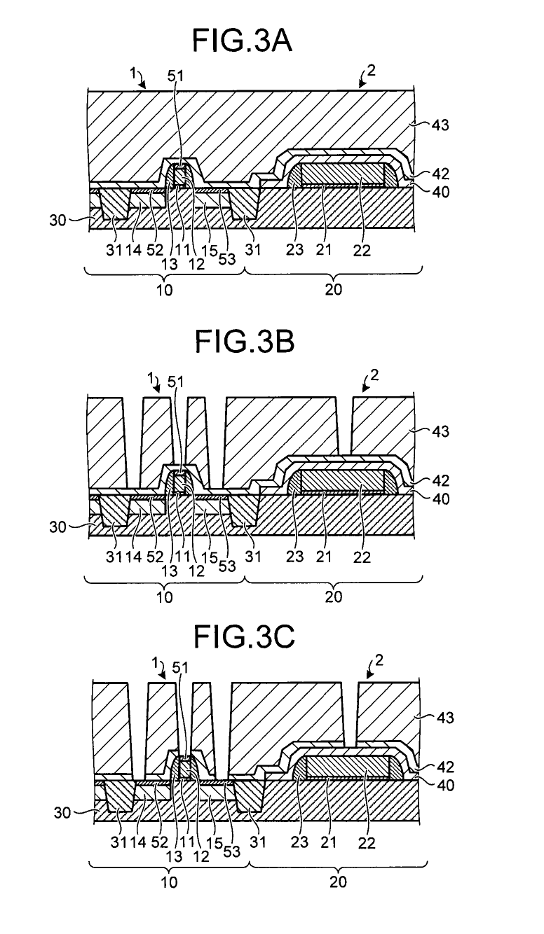

Next, as shown in FIG. 3A, a silicon nitride film 42 that is an insulating film, and an interlayer insulating film 43 formed by a material of silicon oxide are sequentially formed on the first element 1 and the second element 2 onto whose upper surface the blocking film 40 has been formed.

Next, as shown in FIG. 3B, contact holes are formed from an upper surface of the interlayer insulating film 43 toward the gate electrode 12, the source region 14, and the drain region 15 in the first element 1 and the gate electrode 22, the source region, and the drain region in the second element 2.

For example, a resist (not shown) having openings formed at portions above the respective gate electrodes 12, 22, the respective source regions 14, and the respective drain regions 15 may be formed by the photolithography, and the contact holes may be formed by performing the RIE using the aforementioned resist as the mask.

Here, the RIE is performed under an etching condition by which a selective ratio of the silicon oxide and the silicon nitride comes to be at a predetermined ratio or more. That is, the RIE is performed under the etching condition by which an etching of a silicon oxide film is possible while an etching of a silicon nitride film is impossible. Due to this, the contact holes reaching an upper surface of the silicon nitride film 42 from the predetermined positions on the upper surface of the interlayer insulating film 43 are formed.

Next, as shown in FIG. 3C, the silicon nitride film 42 that is present at a bottom surface of each contact hole is removed by performing the RIE with a different etching condition. Due to this, upper surfaces of the salicide layers 51, 52 and 53 of the first element 1 as well as the upper surface of the blocking film 40 above the gate electrode 22, the source region, and the drain region of the second element 2 are exposed. In the RIE for removing the silicon nitride film 42, an etching time is set so that the RIE is performed until the surface of the blocking film 40 formed above the gate electrode 22 of the second element 2 is exposed.

Here, the RIE for removing the silicon nitride film 42 can etch the silicon oxide film. However, as shown in FIG. 3B, the silicon nitride film 42 formed on the gate electrode 12, the source region 14, and the drain region 15 of the first element 1 as well as on the gate electrode 22, the source region, and the drain region of the second element 2 has identical thickness at all of its portions.

Accordingly, by performing the RIE for over the aforementioned etching time on the silicon nitride film 42, the bottom surface of each contact hole does not reach a layer lower than the bottom surface of the silicon nitride film 42 by the RIE.

Due to this, for example, as shown in FIG. 3C, even if a forming position of the contact hole for the source region 14 partially overlaps with a forming position of the STI 31, the contact hole does not reach the STI 31 by the RIE for removing the silicon nitride film 42.

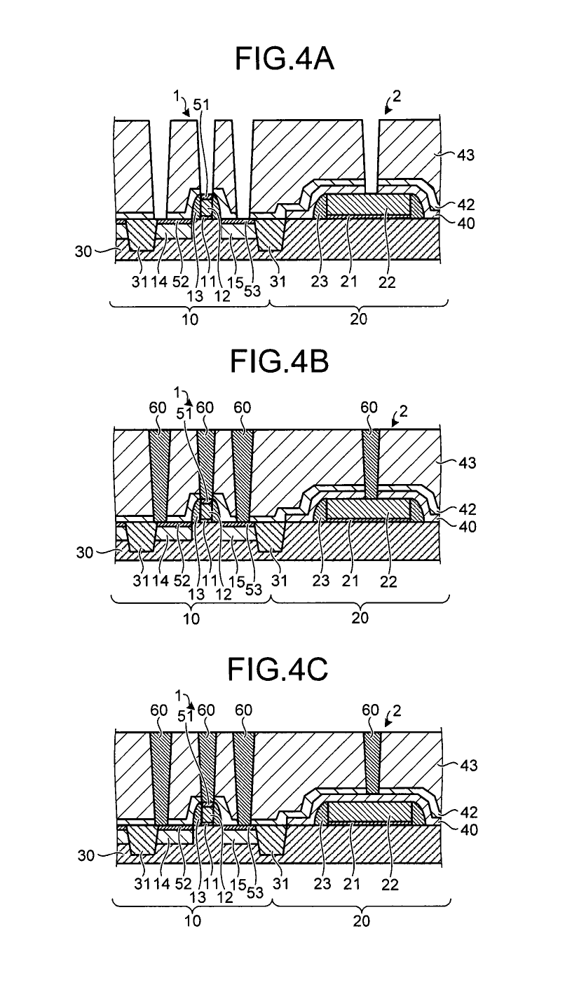

Next, as shown in FIG. 4A, the blocking film 40 formed on the gate electrode 22 in the second element 2 is selectively removed by the ashing, and the upper surface of the gate electrode 22 is exposed. Next, as shown in FIG. 4B, respective one of extracting electrodes 60 is formed inside the corresponding contact hole by embedding metal such as Cu (copper).

Here, as aforementioned in the manufacturing method of the first embodiment, the contact holes do not reach the STI 31. Thus, according to the manufacturing method of the first embodiment, even if metal is embedded in the contact holes, an occurrence of a junction leakage in which current leaks out from the source region 14 of the first element 1 to a substrate side can be prevented.

Note that, in the aforementioned first embodiment, as shown in FIG. 4A, although the extracting electrode 60 is formed after having exposed the upper surface of the gate electrode 22 of the second element 2, as shown in FIG. 3C, the extracting electrode 60 may be formed at the stage of having exposed the upper surface of the blocking film 40 on the gate electrode 22.

In such a case, as shown in FIG. 4C, in the pixel region 20, the extracting electrodes 60 that reach the upper surface of the blocking film 40 on the gate electrode 22, the source region and the drain region from the upper surface of the interlayer insulating film 43 are formed.

In forming the extracting electrodes 60 as above, the blocking film 40 is intervened between the gate electrode 22, the source region and the drain region of the second element 2 and the extracting electrodes 60. Here, as aforementioned, in the manufacturing method of the first embodiment, the gate electrode 22, the source region and the drain region of the second element 2 and the extracting electrodes 60 can be conducted without any problem because the blocking film 40 is formed by conductive amorphous carbon.

Accordingly, by forming the extracting electrodes 60 at the stage of having exposed the upper surface of the blocking film 40 on the gate electrode 22, the ashing for removing the blocking film 40 above the gate electrode 22, the source region and the drain region of the second element 2 can be omitted. Due to this, a reduction in a manufacturing cost and an increase in a throughput can be achieved.

As aforementioned, the manufacturing method of the first embodiment includes a blocking film forming step of forming the blocking film 40, which inhibits the second element 2 from turning into salicide, by the material including at least carbon on the upper surface of the second element 2, of among the first element 1 and the second element 2 formed on the semiconductor substrate.

Due to this, in the manufacturing method of the first embodiment, the blocking film 40 does not need to be removed by the RIE, and can be removed by the ashing; thus, an over-etching of the blocking film 40 upon its removal can be prevented, and a yield can be improved. Specifically, for example, in manufacturing the first element 1 and the second element 2 shown in FIG. 4B, the contact holes can be prevented from reaching a layer lower than the target layer.

Thus, according to the manufacturing method of the first embodiment, the yield of the semiconductor device having the first element whose upper surface has been turned into salicide and the second element 2 whose upper surface has not been turned into salicide can be increased.

Further, the manufacturing method of the first embodiment includes a salicide step of turning the first element 1 into salicide after the blocking film forming step, and an insulating film forming step of forming the insulating film such as the silicon nitride film 42 for example on the upper surface of the first element 1 and the upper surface of the second element 2 onto whose upper surface the blocking film 40 has been formed after the salicide step. Due to this, on the upper surfaces of the first element 1 and the second element 2 onto whose upper surface the blocking film 40 has been formed, the insulating film having uniform thickness is formed.

Further, the manufacturing method of the first embodiment includes an etching step of forming the contact holes by etching, which reach the bottom surface of the insulating film from the upper surface of the insulating film formed in the insulating film forming step to the first element 1 and the second element 2.

According to this, even if other insulating film is formed atop the insulating film formed in the insulating film forming step, the insulating film formed on the upper surface of the first element 1 and the insulating film formed on the upper surface of the second element 2 can be removed by the same etching time.

Thus, according to the manufacturing method of the first embodiment, the contact holes formed by the etching for exposing the upper surface of the blocking film 40 on the second element 2 and the upper surface of the first element 1 can be prevented from reaching a layer lower than the target layer.

Further, the manufacturing method of the first embodiment includes an ashing step of removing the blocking film 40 whose upper surface has been exposed by the etching step by the ashing and causing the bottom surfaces of the contact holes to reach the upper surface of the second element 2.

Due to this, in the manufacturing method of the first embodiment, in forming the contact holes, compared to the case of exposing the upper surface of the second element 2 by the RIE, the upper surface of the second element 2 can be exposed without damaging the upper surface of the second element 2.

Further, the manufacturing method of the first embodiment includes a blocking film forming step of forming the blocking film 40 by the conductive amorphous carbon. Due to this, in the manufacturing method of the first embodiment, as shown in FIG. 4C, the removing step of the blocking film 40 can be omitted in forming the second element 2 onto which the extracting electrode 60 has been formed, so the reduction of manufacturing cost and the increase in the throughput can be achieved.

Further, the semiconductor device of the first embodiment includes the first element 1 and the second element 2 formed on the semiconductor substrate, and the blocking film 40 formed on the upper surface of the second element 2, of among the first element 1 and the second element 2, the blocking film being made by a material including at least carbon and configured to inhibit the second element 2 from turning into salicide. Such a semiconductor device is manufactured by the aforementioned manufacturing method of the first embodiment, so the increase in the yield and the reduction of manufacturing cost can be achieved.

### Second Embodiment

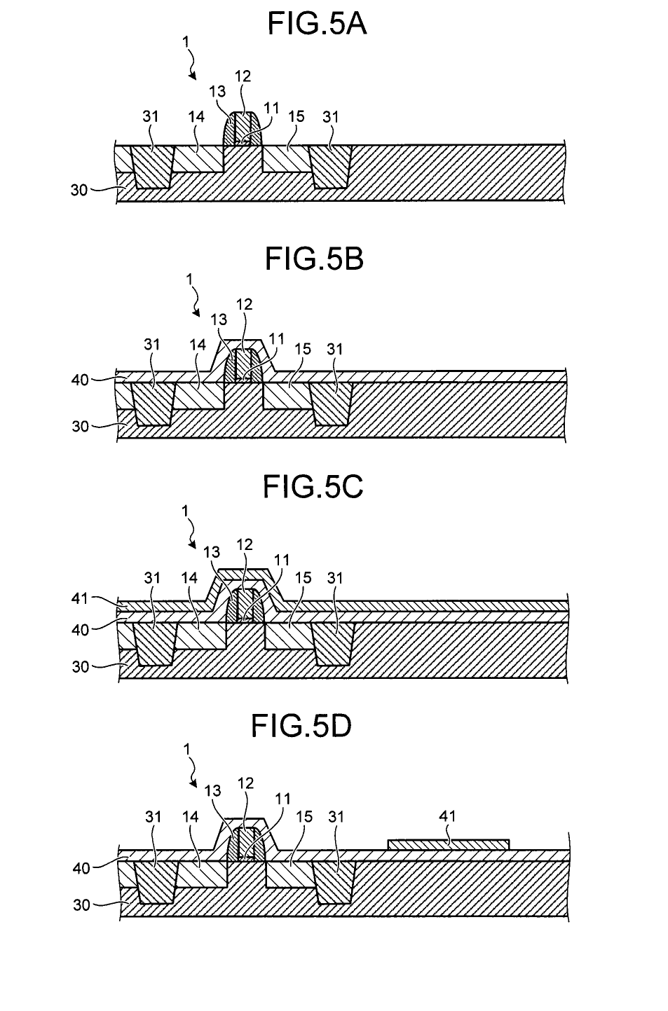

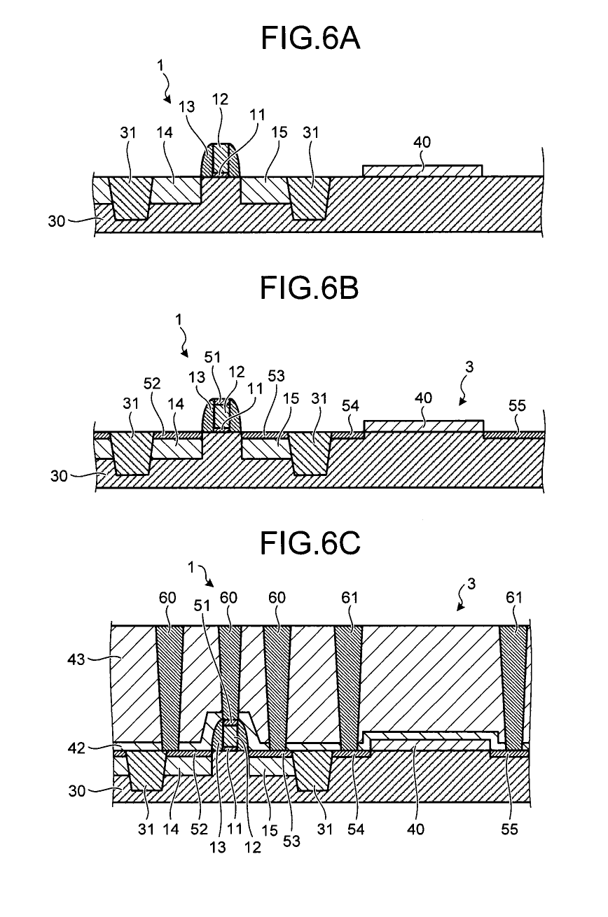

Next, a method of manufacturing a semiconductor device of the second embodiment will be explained with reference to FIG. 5 and FIG. 6. FIG. 5A to FIG. 6C are schematic cross sectional diagrams showing the manufacturing process of the semiconductor device of the second embodiment.

Hereinbelow, the manufacturing process in forming the semiconductor device having the first element 1 similar to the first embodiment and a resistive element (hereafter described as “second element 3”) will be explained. Note that, in the explanation of FIG. 5A to FIG. 6C, part of the explanation thereof will be omitted by giving the same reference signs to constituent elements similar to those shown in FIG. 1A to FIG. 4C.

As shown in FIG. 5A, by the same manufacturing process as in the first embodiment, the gate oxide film 11, the gate electrode 12, the sidewall 13, the source region 14 and the drain region 15 are formed at predetermined positions on the semiconductor layer 30 formed on the semiconductor substrate, whereby the first element 1 is formed. Note that, the first element 1 is separated from other elements on the semiconductor substrate by the STIs 31.

Next, as shown in FIG. 5B, the blocking film 40 formed of a material of amorphous carbon is formed on the upper surface of the semiconductor layer 30 including the first element 1 by for example the plasma CVD. Next, as shown in FIG. 5C, the DARC film 41 is formed on the upper surface of the blocking film 40 by for example the plasma CVD.

Thereafter, as shown in FIG. 5D, the DARC film 41 is selectively remained at a forming position of the second element 3 (refer to FIG. 6B) in the semiconductor layer 30, and a unnecessary portion of the DARC film 41 is removed. Here, for example, a resist selectively covering the DARC film 41 at a portion corresponding to the forming position of the second element 3 (refer to FIG. 6B) for example by a photolithography, and the unnecessary portion of the DARC film 41 is removed by performing the RIE with the resist as a mask.

Next, with the DARC film 41 selectively remained above a forming position of the second element 3 (refer to FIG. 6B) with unnecessary portions removed and used as a mask, a patterning of the blocking film 41 is performed by the ashing.

Due to this, as shown in FIG. 6A, a state in which the blocking film 40 at portions not covered by the DARC film 41 is removed, and the upper surface of the semiconductor layer 30 excluding the forming portion of the second element 3 (refer to FIG. 6B) and the upper surface of the first element 1 are exposed is obtained.

If the patterning of such a blocking film 40 is performed for example by the RIE, the surface of the first element 1 is damaged by the RIE, and a dose loss of impurity ions occur in the source region 14 and the drain region 15, whereby an operation speed of the first element 1 decreases.

In regards to this, in the manufacturing method of the second embodiment, since the blocking film 40 is formed by the amorphous carbon, the patterning of the blocking film 40 can be performed by the ashing instead of the RIE.

Thus, according to the manufacturing method of the second embodiment, since the surface of the first element 1 is not damaged by the RIE, the patterning of the blocking film 40 can be performed without decreasing the operation speed of the first element 1.

Next, heating to a predetermined temperature under the state in which the blocking film 40 is selectively remained at the forming position of the second element 3 is performed, and silicon on the surfaces of the gate electrode 12, the source region 14 and the drain region 15 of the first element 1 and predetermined metal are reacted. Here, for example, Ti (titan) is used as the predetermined metal.

Due to this, as shown in FIG. 6B, the salicide layers 51, 52, and 53 are formed at the upper surface portions of the gate electrode 12, the source region 14 and the drain region 15 of the first element 1, respectively.

At this occasion, at the forming position of the second element 3, salicide layers 54 and 55 having their resistivity lowered are formed at upper surface portions of the semiconductor layer 30 that are not covered by the blocking film 40. On the other hand, the resistivity of the upper surface portion of the semiconductor layer 30 covered by the blocking film 40 is not lowered.

Due to this, the second element 3 that is the resistive element is formed in a region intervened by the salicide layers 54 and 55 at the upper surface portion of the semiconductor layer 30. Note that, the salicide layers 54 and 55 formed on both sides of the second element 3 are electrodes of the second element 3.

Next, as shown in FIG. 6C, the silicon nitride film 42 that is the insulating film, and the interlayer insulating film 43 made by a material of silicon oxide are sequentially formed on the upper surfaces of the first element 1 and the second element 3. Then, after having formed contact holes reaching upper surfaces of the respective salicide layers 51 to 55 from the upper surface of the interlayer insulating film 43, extracting electrodes 60 for the first element 1 and extracting electrodes 61 for the second element 3 are formed by embedding for example Cu inside the respective contact holes.

Here, similar to the first embodiment, in forming the respective contact holes, firstly the RIE is performed under the etching condition by which the selective ratio of the silicon oxide and the silicon nitride comes to be at a predetermined ratio or more. Due to this, the contact holes reaching the upper surface of the silicon nitride film 42 from the upper surface of the interlayer insulating film 43 are formed.

Next, the silicon nitride film 42 that is present at a bottom surface of each contact hole is removed by performing the RIE with different etching condition. At this occasion, since the film thickness of the silicon nitride film 42 is uniform, the etching time until the bottom surfaces of the respective contact holes reaching the upper surfaces of the salicide layers 51 to 55 is the same.

Due to this, as shown in FIG. 6C, even if the forming position of the contact hole for the source region 14 partially overlaps with the forming position of the STI 31, the contact hole does not reach the STI 31 by the RIE for removing the silicon nitride film 42.

Thus, according to the manufacturing method of the second embodiment, even if Cu is embedded in the contact holes, the occurrence of the junction leakage in which the current leaks out from the source region 14 of the first element 1 to the substrate side can be prevented.

As aforementioned, in the manufacturing method of the second embodiment, the blocking film 40 that inhibits the semiconductor layer 30 that is the lower layer thereof from turning into salicide is formed by the material at least including carbon. Due to this, in removing the blocking film 40 from the upper surface of the semiconductor layer 30 except for the forming position of the second element 3 that is the resistive element as well as from the upper surface of the first element 1, the blocking film 40 can be removed by the ashing instead of the RIE.

That is, in the manufacturing method of the second embodiment, the blocking film 40 can be removed from the upper surface of the first element 1 without damaging the first element 1 by the RIE. Thus, according to the manufacturing method of the second embodiment, the second element 3 can be formed on the same semiconductor substrate without decreasing the operation speed of the first element 1.

Note that, in the second embodiment, although the resistive element is formed at the predetermined position of the semiconductor layer 30 as the second element 3, the manufacturing method of this embodiment may be adapted to form the resistive element at positions other than the semiconductor layer 30.

For example, by adapting the manufacturing method of the second embodiment, the resistive element may be formed at an upper surface portion of the gate electrode 22 (refer to FIG. 4C) in the second element 2 formed by the manufacturing method of the first embodiment.

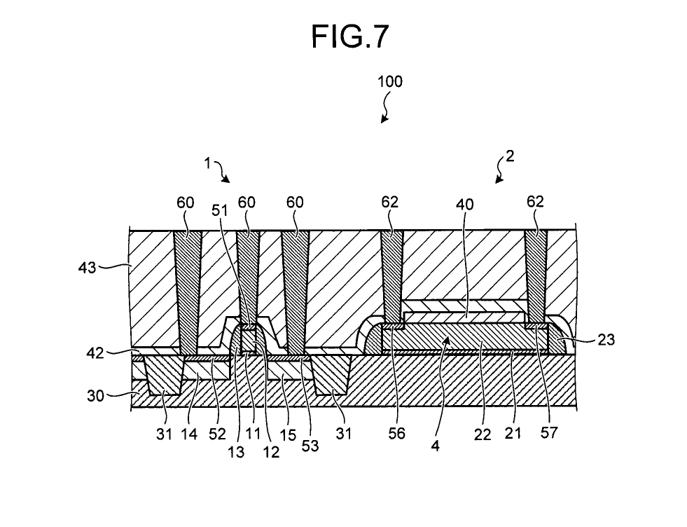

FIG. 7 is a schematic cross sectional view showing a semiconductor device 100 formed by using the manufacturing method of the second embodiment, and that has the resistive element at the upper surface portion of the gate electrode 22. Note that, in FIG. 7, the same reference signs are given to the constituent elements similar to those constituent elements shown in FIG. 1A to FIG. 4C.

As shown in FIG. 7, similar to the semiconductor device manufactured by the manufacturing method of the first embodiment, the semiconductor device 100 includes the first element 1 and the second element 2. Further, the semiconductor device 100 includes a resistive element (hereafter described as “third element 4”) at the upper surface portion of the gate electrode 22 of the second element 2.

In manufacturing such a semiconductor device 100, by steps similar to the steps shown in FIG. 1A to FIG. 10, the blocking film 40 including at least carbon and the DARC film 41 are sequentially formed on the upper surfaces of the first element 1 and the second element 2 formed on the semiconductor substrate.

Thereafter, by the photolithography and the RIE, the DARC film 41 is selectively remained on an upper surface of the blocking film 40 corresponding to a forming position of the third element 4, and unnecessary portions of the DARC film 41 are removed from the upper surface of the blocking film 40.

Specifically, the DARC film 41 is selectively remained on the upper surface of the gate electrode 22 of the second element 2. At this occasion, opening portions that reach the blocking film 40 on the gate electrode 22 from the upper surface of the DARC film 41 are formed at two positions in the DARC film 41 to be selectively remained.

Then, by performing the ashing using the selectively remained DARC film 41 as the mask, the blocking film 40 that is not covered by the DARC film 41 is removed. Due to this, the state in which the upper surface of the first element 1 and predetermined two positions on the upper surface of the gate electrode 22 in the second element 2 are exposed is obtained.

Thereafter, by turning the upper surface of the first element 1 and the predetermined two positions of the upper surface of the gate electrode 22 in the second element into salicide, the salicide layers 51 to 53, 56 and 57 are formed.

Then, the silicon nitride film 42 and the interlayer insulating film 43 are sequentially formed on the upper surfaces of the first element 1, the second element 2, and the third element 4, and contact holes that reach the respective salicide layers 51 to 53, 56 and 57 from the upper surface of the interlayer insulating film 43 are formed. Finally, the extracting electrodes 60 and 62 are formed by embedding Cu respectively in the contact holes, whereby the semiconductor device 100 shown in FIG. 7 is formed.

Accordingly, even in the case of forming the semiconductor device 100 shown in FIG. 7 also, the patterning of the blocking film 40 is performed by the ashing instead of the RIE, and the upper surface of the first element 1 and the predetermined two positions on the upper surface of the gate electrode 22 in the second element 2 can be exposed. Due to this, the first element 1, the second element 2, and the third element 4 can be formed on the same semiconductor substrate without decreasing the operation speed of the first element 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a blocking film by a material including at least carbon on an upper surface of a second element among a first element and the second element formed on a semiconductor substrate, the blocking film configured to inhibit the second element from turning into salicide.

2. The method of manufacturing a semiconductor device according to claim 1, further comprising:
turning the first element into salicide after the forming;
forming an insulating film on upper surfaces of the first element and the second element onto whose upper surface the blocking film has been formed, after the turning; and
forming contact holes that reach a bottom surface of the insulating film from an upper surface of the insulating film by etching toward the first element and the second element.

3. The method of manufacturing a semiconductor device according to claim 2, further comprising:
causing a bottom surface of the contact hole to reach an upper surface of the second element by removing the blocking film by ashing, whose surface has been exposed by the forming contact holes.

4. The method of manufacturing a semiconductor device according to claim 1, wherein
the blocking film is formed by amorphous carbon in the forming the blocking film.

5. The method of manufacturing a semiconductor device according to claim 1, wherein
the semiconductor device is a solid-state imaging device,
the first element is a logic element, and
the second element is a pixel element.

6. The method of manufacturing a semiconductor device according to claim 1, wherein
the forming the blocking film includes:
forming the blocking film on upper surfaces of the first element and the second element; and
selectively removing the blocking film formed on the upper surface of the first element by ashing.

7. The method of manufacturing a semiconductor device according to claim 4, further comprising:
forming extracting electrodes for the first element and the second element by embedding metal inside the contact holes after the causing.

8. The method of manufacturing a semiconductor device according to claim 2, further comprising:
forming extracting electrodes for the first element and the second element by embedding metal inside the contact holes after the forming contact holes.

9. A semiconductor device comprising:
a first element and a second element formed on a semiconductor substrate;
a blocking film that is formed by a material including at least carbon on an upper surface of the second element among the first element and the second element, and configured to inhibit the second element from turning into salicide.

10. The semiconductor device according to claim 9, wherein
the blocking film is formed of amorphous carbon.

11. The semiconductor device according to claim 9, wherein
the semiconductor device is a solid-state imaging device,
the first element is a logic element, and
the second element is a pixel element.
